(19) United States
(12) Patent Application Publication
(10) Pub. No.: US 2021/0188884 A1
(43) Pub. Date: Jun. 24, 2021

(54) TWO DIMENSIONAL ORGANO-METAL HALIDE PEROVSKITE NANORODS

(71) Applicant: Yissum Research Development Company of the Hebrew University of Jerusalem Ltd., Jerusalem (IL)

(72) Inventors: Lioz ETGAR, Jerusalem (IL); Sigalit AHARON, Jerusalem (IL)

(73) Assignee: Yissum Research Development Company of the Hebrew University of Jerusalem Ltd., Jerusalem (IL)

(21) Appl. No.: 16/077,866

(22) PCT Filed: Mar. 8, 2017
(86) PCT No.: PCT/IL2017/050291

§ 371 Date: Aug. 14, 2018

(51) Int. Cl. C07F 7/24; H01L 51/00

(52) U.S. Cl. CPC C07F 7/24; H01L 51/42; H01L 51/0077

(57) ABSTRACT

Organometal halide perovskites are provided as nanoparticles for the construction of efficient light harvesters in photovoltaic solar cells. Further provided are methods of manufacturing the nanoparticles and uses thereof.

### TECHNOLOGICAL FIELD

The invention generally concerns novel perovskite nanoparticles, such as nanorods and nanocubes.

### BACKGROUND

During the past several years, organometal-halide perovskite (OMHP) has been demonstrated to be an efficient light harvester in solar cells; in some cases, it functions simultaneously also as a hole conducting layer in the solar cell. OMHPs can be used in several solar cell architectures, for example mesoporous, planar and without a hole transporting layer. To date, the certified power conversion efficiency of perovskite-based solar cells is 21.0%.

The basic OMHP consists of corner sharing metal halide octahedra, in which a divalent metal cation satisfies the charge balancing. The dimensions of the final perovskite depend on the organic cation size. Small organic cations, such as methylammonium (MA) or formamidinium form the 3D perovskite structure, while larger organic cations, such as ethyl ammonium, form the 2D perovskite structure.

Confined perovskite nanoparticles could lead to highly efficient optoelectronic devices, taking advantage of their superior bulk properties as well as the nanoscale properties. Moreover, it has been reported that reducing the size of the OMHPs to the nanometric scale could enhance the photoluminescence (PL) emission.

Currently, there are several reports on the synthesis of perovskite quantum dots (QDs); most of which relate to the synthesis and characterization of all-inorganic perovskite QDs. The synthetic technique of inorganic perovskite QDs is based on ionic metathesis reaction, in which the kinetics of the nucleation and the growth are very fast. This route is not usable in the case of OMHP due to temperature and stability issues, and there are also dissolving and precipitation problems. Due to the temperature and the stability issues, which makes the formation of standalone perovskite QDs/nanostructures to be challenging, a new synthetic route should be developed.

In a recent paper, Schmidt et al [1] reported the preparation of MAPbBr₃ nanoparticles (NPs) using (in combination with oleic acid) a medium sized alkyl-amine that controls the particles' growth and enables dispersing them in organic solvents. The MAPbBr₃ NPs demonstrated narrow emission with approximately 20% quantum yield (QY).

Zhu et al [2] synthesized MAPbX₃ (X=I⁻ or Br⁻) NPs in a mixture of several morphologies, being a mixture of dots, rods, wires and sheets in the same sample. Synthesis of a population of nanorods only was not possible. Generally, the synthetic process included the injection of several precursors into vigorously stirred toluene. In this method, besides the QDs (which were not stable and went through fast aggregation), all the synthesized morphologies had one or two nanometric dimension(s), while the third dimension was in the micrometric size. Notably, the PL-QY of the various morphologies was very low.

Zhang et al [3] used a similar synthetic approach and synthesized highly luminescent MAPbX₃ QDs (X=I⁻, Br⁻ or Cl⁻). It was shown that by alternating the halides composition, different optical properties were achieved. The strong PL of the QDs originates from the increased exciton binding energy in combination with bromide-rich surface passivation.

Huang et al [4,5] showed that by using the injection method of several precursors into vigorously stirred toluene the optical properties of MAPbBr₃ could be controlled by changing the precipitation temperature. Additional synthesis method showed the fabrication of OMHP QDs by emulsion, which assists in the size tuning of MAPbBr₃ QDs.

### REFERENCES

[1] Schmidt, L. C.; Pertegas, A.; Gonzalez-Carrero, S.; Malinkiewicz, O.; Agouram, S.; Espallargas, G. M.; Bolink, H. J.; Galian, R. E.; Perez-Prieto, J. J. Am. Chem. Soc. 2014, 136, 850-853.
[2] Zhu, F.; Men, L.; Guo, Y.; Zhu, Q.; Bhattacharjee, U.; Goodwin, P. M.; Petrich, J. W.; Smith, E. A.; Vela, J. ACS Nano 2015, 9, 2948-2959.
[3] Zhang, F.; Zhong, H.; Chen, C.; Wu, X.; Hu, X.; Huang, H.; Han, J.; Zou, B.; Dong, Y. ACS Nano 2015, 9, 4533-4542.
[4] Huang, H.; Susha, A. S.; Kershaw, S. V.; Hung, T. F.; Rogach, A. L. Advances Science 2015, 2, 1500194.
[5] Huang, H.; Zhao, F.; Liu, L.; Zhang, F.; Wu, X.; Shi, L.; Zou, B.; Pei, Q.; Zhong, H. ACS Appl. Mater. Interfaces 2015, 7, 28128-28133.

### GENERAL DESCRIPTION

Perovskite materials are efficient light harvesting materials that are used in optoelectronic devices, such as, photovoltaic solar cells. Perovskite materials are used mainly in their “bulk” form in optoelectronic devices. Confined perovskite nanostructures could be a promising route to efficient optoelectronic devices, taking advantage of the superior bulk properties of the material as well as the nanoscale properties.

The inventors of the present invention have developed a unique, simple and cost effective process for the production of a novel, size-specific family of perovskite nanoparticles characterized by their nanometric size and morphology. The novel perovskite nanoparticles (NPs) of the invention, in a form mainly selected from nanorods and nanocubes, are of high quality and defined morphology. The nanorods and nanocubes of the invention may be used in a variety of optoelectronic applications, such as light emitting diodes, lasing, solar cells and sensors. The nanoparticles of the invention are not nanowires, nor a nanoplates.

Organometal halide perovskites are efficient light harvesters in photovoltaic solar cells that are used mainly in their “bulk” form. Herein, the inventors present facile low temperature synthesis of two-dimensional (2D), e.g., lead halide perovskite nanorods and nanocubes. These 2D perovskite nanoparticles show a shift to higher energies in the absorbance and in the photoluminescence compared to the bulk material supporting their 2D structure. In addition, by alerting the halide composition, it was possible to tune the optical properties of the nanoparticles. Fast Fourier Transform, electron diffraction and x-ray diffraction show the tetragonal structure of these nanoparticles. By varying the ligands ratio (e.g. octylammonium to oleic acid) in the synthesis, it was possible to provide the formation mechanism of these novel 2D perovskite nanoparticles, that are useful in a variety of optoelectronic applications, such as light emitting diodes, lasing, solar cells and sensors.

The present invention thus provides in one aspect a perovskite nanoparticle, in the form of a nanorod or a nanocube, the nanoparticle comprises or consists at least one perovskite material, being optionally at least one organic-inorganic material. In some embodiments, the perovskite material is a lead halide perovskite (a perovskite comprising one or more lead atoms, as exemplified, and one or more halide anions, as further exemplified herein).

In some embodiments, the nanoparticle has a length of between 3 and 200 nm. In some embodiments, the nanoparticle has a length of between 3 and 20 nm.

In some embodiments, the nanoparticle is of an aspect ratio ((length of long axis)/(length of short axis)) of between 1 (in case of nanocubes) and 100 (for nanorods).

The invention further provides an organic-inorganic perovskite nanoparticle, wherein the organic-inorganic perovskite nanoparticle is a nanorod or a nanocube.

The invention further provides an organic-inorganic perovskite nanoparticle, wherein the organic-inorganic perovskite nanoparticle having an aspect ratio of between 1 and 100.

The “nanorod” of the invention is a nano-sized “rod-like nanoparticle” having a defined long and short axis. The size of the nanorod is given as the length (long axis or Z axis) of the particle, the width (short axis or diameter or X-Y axis) and/or the particle aspect ratio. The faceted shape has substantially flat regions on the surface of the nanoparticle.

The elongated shape may be of any anisotropic, non-spherical form, known also as rod-like, rice, elliptic, cylindrical, an elongated rectangle, an elongated tetragon, an elongated octahedron, an elongated pentagon, an elongated hexagon, an elongated heptagon, an elongated octagon, an elongated nonagon, an elongated decagon, an elongated dodecagon and others.

The nanorods have an aspect ratio that is greater than 1, and as further selected.

The “nanocubes” are nanostructure, cubic in shape, characterized by substantially flat facets, wherein the axes lengths are approximately equal. Thus, the aspect ratio of the nanocubes is 1 or substantially 1. Any deviations from such an aspect ratio would encompass nanorods, as herein defined.

In some embodiments, the nanorod is a nanocrystal with extended growth along one of its axis, maintaining relatively small dimensions of the two other axes.

The length of the longest axis (or Z axis) of a nanorod may be less than 800 nm. In some embodiments, the longest axis of the nanorod is less than 600 nm, less than 500 nm, less than 400 nm, less than 300 nm, less than 250 nm, less than 200 nm, less than 150 nm, less than 100 nm, less than 80 nm, less than 50 nm, less than 40 nm, less than 30 nm, less than 20 nm or less than 10 nm.

The length of the longest axis of a nanorod may be greater than 10 nm, greater than 20 nm, greater than 30 nm, greater than 40 nm, greater than 50 nm, greater than 80 nm, greater than 100 nm, greater than 150 nm, greater than 200 nm, greater than 250 nm, greater than 300 nm, greater than 400 nm, or greater than 500 nm.

The length of the longest axis of a nanorod may be in the range of 3 to 800 nm, 3 to 600 nm, 3 to 500 nm, 3 to 400 nm, 3 to 300 nm, 3 to 250 nm, 3 to 200 nm, 3 to 150 nm, 3 to 100 nm, 3 to 80 nm, 3 to 50 nm, 3 to 40 nm or 3 to 30 nm.

The length of the short axis of a nanorod may be less than 200 nm, less than 180 nm, less than 150 nm, less than 130 nm, less than 100 nm, less than 80 nm, less than 70 nm, less than 60 nm, less than 50 nm, less than 40 nm, less than 30 nm, less than 20 nm, less than 10 nm, less than 8 nm or less than 5 nm.

The length of the short axis of a nanorod may be greater than 1 nm, greater than 2 nm, greater than 3 nm, greater than 4 nm, greater than 5 nm, greater than 6 nm, greater than 7 nm, greater than 8 nm, greater than 10 nm, or greater than 15 nm.

The length of the short axis of a nanorod may be in the range of 1 to 200 nm, 1 to 150 nm, 1 to 100 nm, 1 to 80 nm, 1 to 70 nm, 1 to 60 nm, 1 to 50 nm, 1 to 40 nm, 1 to 30 nm, 1 to 20 nm, 1 to 10 nm, 1 to 8 nm or in the range of 1 to 7 nm.

In some embodiments, the short axis of a nanorod is between 1 and 10 nm and the long axis of the nanorod is between 10 and 25 nm.

In some embodiments, the length of the short axis of a nanorod and the length of the long axis of the nanorod may be selected to provide the nanorod with an aspect ratio of between 1 and 100. In some embodiments, the short axis is selected to be between 1 and 10 nm and the long axis is selected accordingly from between 10 and 25 nm. In other embodiments, the long axis is selected to be between 10 and 25 nm the short axis is selected accordingly from 1 and 10 nm.

The nanorod may have an aspect ratio larger than 1. In some embodiments, the aspect ratio is greater than 1.1, 1.2 or 1.3. In some embodiments, the aspect ratio is between 1 and 1.1, between 1.1 and 1.2, between 1.2 and 1.3 or between 1.05 and 1.1.

In other embodiments, the aspect ratio is larger than 2, larger than 3, larger than 4, larger than 5, larger than 6, larger than 7, larger than 8, larger than 9, larger than 10, larger than 15, larger than 20, larger than 25 or larger than 30.

The nanorod may have an aspect ratio smaller than 50, smaller than 40, smaller than 35, smaller than 30, smaller than 25, smaller than 20, smaller than 15, smaller than 10, smaller than 8, smaller than 7, smaller than 6, smaller than 5, smaller than 4, or smaller than 3.

The nanorod may have an aspect ratio between 1.3 and 50, between 1.3 and 30, between 1.3 and 25, between 1.8 and 20, between 1.3 and 15, between 1.3 and 10, between 1.3 and 7, between 2 and 50, between 2 and 30, between 2 and 25, between 2 and 20, between 2 and 15, between 2 and 10, or between 2 and 7.

In some embodiments, the nanocube is a nanocrystal with axes of approximately equal lengths. The length of the each of the nanocube axes may be less than 800 nm. In some embodiments, the length is less than 600 nm, less than 500 nm, less than 400 nm, less than 300 nm, less than 250 nm, less than 200 nm, less than 150 nm, less than 100 nm, less than 80 nm, less than 50 nm, less than 40 nm, less than 30 nm, less than 20 nm or less than 10 nm.

The length of each of the nanocube axes may be greater than 10 nm, greater than 20 nm, greater than 30 nm, greater than 40 nm, greater than 50 nm, greater than 80 nm, greater than 100 nm, greater than 150 nm, greater than 200 nm, greater than 250 nm, greater than 300 nm, greater than 400 nm or greater than 500 nm.

In some embodiments, the length of each of the nanocube axes may be between 3 to 800 nm, between 3 to 600 nm, between 3 to 500 nm, between 3 to 400 nm, between 3 to 300 nm, between 3 to 250 nm, between 3 to 200 nm, between 3 to 150 nm, between 3 to 100 nm, between 3 to 80 nm, between 3 to 50 nm, between 3 to 40 nm or between 3 to 30 nm.

The nanocube has an aspect ratio of 1, or may be said to have an aspect ratio of between 1.0 and 1.3, between 1 and 1.1, between 1.1 and 1.2, between 1.2 and 1.3 or between 1.05 and 1.1, in cases an exact decimal accuracy cannot be measured.

The “perovskite material” refers to a material comprising or consisting one or more perovskite species, and encompass any perovskite structure known in the art. The perovskite material is typically characterized by the structural motif AMX₃, having a three-dimensional network of corner-sharing MX₆ octahedra, wherein M is a metal cation that may adopt an octahedral coordination of the X anions, and wherein A is a cation typically situated in the 12-fold coordinated holes between the MX₆ octahedra.

In some embodiments, the perovskite material is a lead halide.

In some embodiments, the perovskite material is of the formula AₗMₙXₚ, wherein:

A is selected from organic cations, metal cations, inorganic cations and any combination of such cations;

M is a metal cation or any combination of metal cations;

X is an anion or a combination of anions;

n is between 1 to 60;

p is between 1 to 60; and

l is between 1 to 60.

In some embodiments, any one of n, p and 1, independently may be between 1 and 20.

In some embodiments, A, M and X, represent each a single element and in other embodiments, each of A, M and X, represents more than one element.

In some embodiments, the perovskite material is of the formula AMX₃ or AMX₄ or A₂MX₄ or A₃MX₅ or A₂A′MX₅ or AMX₃₋ₙX′ₙ, wherein:

A and A′ are independently selected from organic cations, metal cations and any combination of such cations;

M is a metal cation or any combination of metal cations;

X and X′ are independently selected from anions and any combination of anions; and

n is between 0 to 3.

Repeating or multiple elements in any of the above perovskite formulae (e.g., A₂ or X₄ in A₂MX₄) may be the same or different. For example, A₂MX₄ may actually be of the structure AA′MXX′X″X′″.

In some embodiments, the perovskite material is a single species of a perovskite material. In other embodiments, the perovskite material is a combination of two or more (several, plurality) different species of different perovskite materials. In some embodiments, the number of different species of different perovskite materials may be 2 or 3 or 4 or 5 or 6 or 7 or 8 or 9 or 10 perovskite different perovskite species.

The cation and anion moieties may be in any valence number. In some embodiments, the cation and/or the anion have a valence number of 1 or 2 or 3 or 4 or 5 or 6 or 7. In some embodiments, the cation and/or the anion is a monovalent atom. In some embodiments, the cation and/or the anion is a divalent atom. In some embodiments, the cation and/or the anion is a trivalent atom.

The metal cations may be selected from metal element of Groups IIIB, IVB, VB, VIB, VIIB, VIIIB, IB, IIB, IIIA, IVA and VA of block d of the Periodic Table of the Elements.

In some embodiments, the metal cation is Li or Mg or Na or K or Rb or Cs or Be or Ca or Sr or Ba, Sc or Ti or V or Cr or Fe or Ni or Cu or Zn or Y or La or Zr or Nb or Tc or Ru or Mo or Rh or W or Au or Pt or Pd or Ag or Co or Cd or Hf or Ta or Re or Os or Ir or Hg or B or Al or Ga or In or Tl or C or Si or Ge or Sn or Pb or P or As or Sb or Bi or O or S or Se or Te or Po or any combination thereof.

In some embodiments, the metal cation is a transition metal selected from Groups IIIB, IVB, VB, VIB, VIIB, VIIIB, IB and IIB of block d the Periodic Table. In some embodiments, the transition metal is a metal selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg or any combination thereof.

In some embodiments, the metal is Pb.

In some embodiments, the metal cation is a post-transition metal selected from Group IIIA, IVA and VA. In some embodiments, the metal cation is Al or Ga or In or Tl or Sn or Pb or Bi or any combination thereof.

In some embodiments, the metal cation is a semi-metal selected from Group IIIA, IVA, VA and VIA of the Periodic Table. In some embodiments, the metal cation is B or Si or Ge or As or Sb or Po or any combination thereof.

In some embodiments, the metal cation is an alkali metal selected from Group IA. In some embodiments, the metal cation is an alkali metal Li or Mg or Na or K or Rb or Cs.

In some embodiments, the metal cation is an alkaline earth metal selected from Group IIA. In some embodiments, the metal cation is Be or Ca or Sr or Ba.

In some embodiments, the metal cation is a lanthanide element such as Ce or Pr or Gd or Eu or Tb or Dy or Er or Tm or Nd or Yb or any combination thereof.

In some embodiments, the metal cation is an actinides element such as Ac or Th or Pa or U or Np or Pu or Am or Cm or Bk or Cf or Es or Fm or Md or No or Lr or any combination thereof.

In some embodiments, the metal cation is a divalent metal cation. Non-limiting examples of divalent metals include Cu⁺², Ni⁺², Co⁺², Fe⁺², Mn⁺², Cr⁺², Pd⁺², Cd⁺², Ge⁺², Sn⁺², Pb⁺², Eu⁺² and Yb⁺².

In some embodiments, the metal cation is a trivalent metal cation. Non-limiting examples of trivalent metals include Bi⁺³ and Sb⁺³.

In some embodiments, the metal cation is Pb⁺².

The anion may be a halide anion or a chalcogenide anion or an organic anion or an oxoanion or any combination thereof. In some embodiments, the anion is an anion such as O⁻², N⁻³, S⁻² or any combination thereof.

In some embodiments, the anion is a halide anion selected from F, Cl, Br, I, At and any combination thereof.

In some embodiments, the anion is selected from anions of an atom selected from S, Se, Te and any combination thereof.

In some embodiments, the anion is selected amongst organic anions such as acetate (CH₃COO⁻), formate (HCOO⁻), oxalate (C₂O₄⁻²), cyanide (CN⁻) or any combination thereof.

In some embodiments, the anion is a oxoanion such as AsO₄⁻³, AsO₃⁻³, CO₃⁻², HCO₃⁻, OH⁻, NO₃⁻, NO₂⁻, PO₄⁻³, HPO₄⁻², SO₄⁻², HSO₄⁻, S₂O₃⁻², SO₃⁻², ClO₄⁻, ClO₃⁻, ClO₂⁻, OCl⁻, IO₃⁻, BrO₃⁻, OBr⁻, CrO₄⁻², Cr₂O₇⁻² or any combination thereof.

In some embodiments, the anion may be selected from Br⁻, I⁻, NCS⁻, CN⁻, and NCO⁻. In further embodiments, the anion may be selected from IBr⁻³, Cl₂I⁻³, Br₂I⁻³ and I₂Cl⁻³.

In some embodiments, the perovskite material is an inorganic perovskite material.

In some embodiments, A and M are metal cations, e.g., the perovskite material is a metal oxide perovskite material.

In further embodiments, the perovskite material is of the formula AMX₃, wherein A is metal cation, i.e., M′MX₃. In further embodiments, the perovskite material is of the formula M′MX′X₂. In some embodiments, the perovskite material comprises or is selected from CsPbI₂Cl, CsPbICl₂, CsPbI₂F, CsPbIF₂, CsPbI₂Br and CsPbIBr₂.

In some embodiments, the perovskite material comprises or is selected from CsSnI₂F, CsSnIF₂, CsSnI₂Cl, CsSnICl₂, CsSnI₂Br and CsSnIBr₂.

In some embodiments, A is an organic cation and M is a metal cation, i.e., the perovskite material is an organic-inorganic perovskite material.

In some embodiments, the perovskite material is organic-inorganic perovskite material.

In other embodiments, A is an organic cation and M is a metal cation, i.e., the perovskite material is an organic-inorganic perovskite material. The organic cations are cations comprising at least one organic moiety (containing one or more carbon chain or hydrocarbon chain or one or more organic group). The organic moiety may be selected from substituted or unsubstituted alkyl, substituted or unsubstituted alkenyl, substituted or unsubstituted alkynyl, substituted or unsubstituted cycloalkyl, substituted or unsubstituted cycloalkenyl, substituted or unsubstituted cycloalkynyl, substituted or unsubstituted aryl, substituted or unsubstituted heteroaryl, substituted or unsubstituted heterocyclyl, substituted or unsubstituted —NR₁R₂, substituted or unsubstituted —OR₃, substituted or unsubstituted —SR₄, substituted or unsubstituted —S(O)R₅, substituted or unsubstituted alkylene-COOH, and substituted or unsubstituted ester. Any of the variable groups denoted herein by “R” refers to one or more group selected from hydrogen, alkyl, alkenyl, alkynyl, cycloalkyl, cycloalkenyl, cycloalkynyl, aryl, heteroaryl, heterocyclyl, halogen, alkylene-COOH, ester, —OH, —SH, and —NH, as defined herein or any combination thereof. In some embodiments, the number of R groups may be 0 or 1 or 2 or 3 or 4 or 5 or 6 or 7 or 8 or 9 or 20. As used herein, the group R refers generically to any specific R used herein, unless a specific definition is provided; in other words, the aforementioned definition refers to any of the R groups, e.g., R′, R″, R′″, R″″, R₂, R₃, R₄, R₅, R₆, R₇, R₈, etc, unless otherwise specifically noted.

In the organic moieties comprising the organic-inorganic hybrid material, the following definitions are applicable:
“alkyl”, “alkenyl” and “alkynyl” carbon chains, if not specified, refers to carbon chains each containing from 1 to 20 carbons, or 1 or 2 to 16 carbons, and are straight or branched. Each such group may be substituted. In some embodiments, the carbon chain contains 1 to 10 carbon atoms. In some embodiments, the carbon chain contains 1 to 6 carbon atoms. In some embodiments, the carbon chain contains 2 to 6 carbon atoms. Alkenyl carbon chains may contain from 2 to 20 carbons, or 2 to 18 carbons, or 2 to 16 carbons, or 2 to 14 carbons, or 2 to 12 carbons, or 2 to 10 carbons, or 2 to 8 carbons, or 2 to 6 carbons, or 2 to 4 carbons. The alkenyl carbon chain may similarly contain 1 to 8 double bonds, or 1 to 7 double bonds, or 1 to 6 double bonds, or 1 to 5 double bonds, or 1 to 4 double bonds, or 1 to 3 double bonds, or 1 double bond, or 2 double bonds. Alkynyl carbon chains from 2 to 20 carbons, or 2 to 18 carbons, or 2 to 16 carbons, or 2 to 14 carbons, or 2 to 12, or 2 to 10 carbons, or 2 to 8 carbons, or 2 to 6 carbons, or 2 to 4 carbons. The alkynyl carbon chain may similarly contain 1 to 8 triple bonds, or 1 to 7 triple bonds, or 1 to 6 triple bonds, or 1 to 5 triple bonds, or 1 to 4 triple bonds, or 1 to 3 triple bonds, or 1 triple bond, or 2 triple bonds. Exemplary alkyl, alkenyl and alkynyl groups include, but are not limited to, methyl, ethyl, propyl, isopropyl, isobutyl, n-butyl, sec-butyl, tert-butyl, isohexyl, allyl (propenyl) and propargyl (propynyl).
“cycloalkyl” refers to a saturated mono- or multi-cyclic ring system, in certain embodiments of 3 to 10 carbon atoms, in other embodiments 3 to 6 carbon atoms; cycloalkenyl and cycloalkynyl refer to mono- or multicyclic ring systems that respectively include at least one double bond and at least one triple bond. Cycloalkenyl and cycloalkynyl groups may, in some embodiments, may contain between 3 to 10 carbon atoms, in further embodiments, between 4 to 7 carbon atoms and cycloalkynyl groups, in further embodiments, containing 8 to 10 carbon atoms. The ring systems of the cycloalkyl, cycloalkenyl and cycloalkynyl groups may be composed of one ring or two or more rings which may be joined together in a fused, bridged or spiro-connected fashion.
“aryl” refers to aromatic monocyclic or multicyclic groups containing from 6 to 10 carbon atoms. Aryl groups include, but are not limited to groups such as unsubstituted or substituted fluorenyl, unsubstituted or substituted phenyl, and unsubstituted or substituted naphthyl.
“heteroaryl” refers to a monocyclic or multicyclic aromatic ring system, in certain embodiments, of about 5 to about 15 members where one or more, in some embodiments 1 to 3, of the atoms in the ring system is a heteroatom, that is, an element other than carbon, including e.g., nitrogen, oxygen or sulfur. The heteroaryl group may be optionally fused to a benzene ring. Heteroaryl groups include, but are not limited to, furyl, imidazolyl, pyrimidinyl, tetrazolyl, thienyl, pyridyl, pyrrolyl, thiazolyl, isothiazolyl, oxazolyl, isoxazolyl, triazolyl, quinolinyl and isoquinolinyl.
“heterocyclyl” refers to a saturated mono- or multi-cyclic ring system, in one embodiment of 3 to 10 members, in another embodiment of 4 to 7 members, in a further embodiment of 5 to 6 members, where one or more, in certain embodiments, 1 to 3, of the atoms in the ring system is a heteroatom, that is, an element other than carbon, including but not limited to, nitrogen, oxygen or sulfur. In embodiments where the heteroatom(s) is nitrogen, the nitrogen is optionally substituted with alkyl, alkenyl, alkynyl, aryl, heteroaryl, aralkyl, heteroaralkyl, cycloalkyl, heterocyclyl, cycloalkylalkyl, heterocyclylalkyl, acyl, guanidine, or the nitrogen may be quaternized to form an ammonium group where the substituents are selected as above.
“—NR₁R₂” refers to an amine group wherein R₁ and R₂ are independently selected from hydrogen, alkyl, alkenyl, alkenyl, cycloalkyl, cycloalkenyl, cycloalkynyl, aryl, heteroaryl, heterocyclyl, ester and carbonyl, each as defined herein or alternatively known in the art.
“—OR₃” refers to a hydroxyl group or an alkoxy group or derivative, wherein R₃ is selected from hydrogen, alkyl, alkenyl, alkenyl, cycloalkyl, cycloalkenyl, cycloalkynyl, aryl, heteroaryl, heterocyclyl, halogen, sulfinyl, ester and carbonyl.
“—SR₄” refers to a thiol group or a thioether group or derivative, wherein R₄ is selected from hydrogen, alkyl, alkenyl, alkenyl, cycloalkyl, cycloalkenyl, cycloalkynyl, aryl, heteroaryl, heterocyclyl, halogen, sulfinyl, ester and carbonyl.
“—S(O)R₅” refers to a sulfinyl group, wherein R₅ is selected from hydrogen, alkyl, alkenyl, alkenyl, cycloalkyl, cycloalkenyl, cycloalkynyl, aryl, heteroaryl, heterocyclyl, halogen, sulfinyl, ester and carbonyl.
“ester” refers to —C(O)OR₈ in which R₈ is selected from hydrogen, alkyl, alkenyl, alkenyl, cycloalkyl, cycloalkenyl, cycloalkynyl, aryl, heteroaryl, heterocyclyl, halogen, —NR₁R₂, sulfinyl, carbonyl, —OR₃, SR₄, —S(O)R₅—OH, —SH and —NH.

The term “substituted” refers to any group or any ligand as defined herein above having (further substituted) one or more substituent, wherein the substituent is a ligand as defined herein above. In some embodiments, the substituent is selected from hydrogen, alkyl, alkenyl, alkynyl, cycloalkyl, cycloalkenyl, cycloalkynyl, aryl, heteroaryl, heterocyclyl, halogen, alkylene-COOH, ester, —OH, —SH, and —NH. In some embodiments, the number of substituents on a certain ligand is 0 or 1 or 2 or 3 or 4 or 5 or 6 or 7 or 8 or 9 or 20 substituents.

In some embodiments, the perovskite structure is an organic-inorganic perovskite structure. In some embodiments, the organic-inorganic perovskite structure is selected from (R—NH₃)₂MX₄ and (NH—R—NH)MX (wherein X may be Cl⁻¹, Br⁻¹, or I⁻¹ and R may be selected as above); the M cation may be a divalent or trivalent metal that satisfies charge balancing and adopts (octahedral) anion coordination.

In some embodiments, the perovskite material comprises an organic cation that is an organic monovalent cation or a divalent or a trivalent or of any other valency.

In some embodiments, the organic cation is a primary, a secondary, a tertiary or a quaternary organic ammonium compound, including N-containing hetero-rings and ring systems.

In some embodiments, the organic cation is a carbon (hydrocarbon) chain comprising one or more heteroatoms. The heteroatom(s) may be selected from N, O and S. In some embodiments, the number of heteroatoms is 1 or 2 or 3.

In some embodiments, the heteroatom is a nitrogen atom.

In some embodiments, the carbon chain comprises one or more halogens.

In some embodiments, the carbon chain comprises a heterocyclyl and/or a heteroaryl.

In some embodiments, the organic cation is a monovalent or a bivalent cation or of any other valency, which may be a primary, a secondary, a tertiary or a quaternary organic amine or ammonium compound, e.g., having two positively charged nitrogen atoms.

In some embodiments, in a perovskite structure as defined above, the cation (A or A′) is an organic cation of the structure (RR′R″R′″N)⁺, wherein each of the R groups may be selected, independently, as defined herein. In some embodiments, the cation is selected from RNH₃, RR′NH₂, R R′R″NH, NH₃RNH₃ and any combination thereof. In some embodiments, the cation is selected from RNH═R′, NH₂═R, RN═R′R″, R′═N═R, RR′N═R═NR″R′, H₂N═R═NH₂ and RR′N═CHNR″R′. In some embodiments, the cation is (H₂N═CHNH₂)⁺ or any combination thereof.

In some embodiments, the perovskite material is of the formula AMX₃.

In further embodiments, the perovskite material is of the formula AMX′X₂.

In yet further embodiments, the perovskite material is of the formula RNH₃MX′X₂.

In some embodiments, the perovskite material comprises or is selected from CH₃NH₃PbF₃, CH₃NH₃PbCl₃, CH₃NH₃PbI₃, CH₃NH₃PbBr₃, CH₃NH₃PbBrI₂, CH₃NH₃PbBrCl₂, CH₃NH₃PbIBr₂, CH₃NH₃PbICl₂, CH₃NH₃PbClBr₂ and CH₃NH₃PbI₂Cl. In some embodiments, the perovskite material comprises or is selected from CH₃NH₃SnICl₂, CH₃NH₃SnBrI₂, CH₃NH₃SnBrCl₂, CH₃NH₃SnF₂Br, CH₃NH₃SnIBr₂, CH₃NH₃SnF₂I, CH₃NH₃SnClBr₂, CH₃NH₃SnI₂Cl and CH₃NH₃SnF₂Cl.

In further embodiments, the perovskite material is of the formula RNH₃MX₃. In some embodiments, the perovskite material comprises or is selected from CH₃NH₃PbF₃, CH₃NH₃PbCl₃, CH₃NH₃PbI₃ and CH₃NH₃PbBr₃. In some embodiments, the perovskite material is CH₃NH₃PbI₃.

In further embodiments, the perovskite material is of the formula (NH₂═CH—NH₂) MX₃. In some embodiments, the perovskite material comprises or is selected from (NH₂═CH—NH₂)PbBr₃, (NH₂═CH—NH₂)PbI₃, (NH₂═CH—NH₂)PbCl₃, (NH₂═CH—NH₂)PbFCl₂, (NH₂═CH—NH₂)PbBrCl₂, (NH₂═CH—NH₂)PbICl₂, (NH₂═CH—NH₂)PbFCl₂, (NH₂═CH—NH₂)PbFBr₂, (NH₂═CH—NH₂)PbFI₂ and (NH₂═CH—NH₂)PbIBr₂.

In some embodiments, the perovskite material is of the formula RₗA_{q}MₙXₚ, wherein

A is selected from organic cations, metal cations, inorganic cations and any combination of such cations;

R is selected from organic cations;

M is a metal cation or any combination of metal cations;

X is selected from anions and any combination of anions;

n is equal or between 1 to 60;

p is equal or between 1 to 60;

l is equal or between 1 to 60; and

q is equal or between 0 to 60.

In some embodiments, n and/or p and/or 1 and/or q is 1 or 2 or 3 or 4 or 5 or 6 or 7 or 8 or 9 or 10 or 11 or 12 or 13 or 14 or 15 or 16 or 17 or 18 or 19 or 20 or 21 or 22 or 23 or 24 or 25 or 26 or 27 or 28 or 29 or 30 or 31 or 32 or 33 or 34 or 35 or 36 or 37 or 38 or 39 or 40 or 41 or 42 or 43 or 44 or 45 or 46 or 47 or 48 or 49 or 50 or 51 or 52 or 53 or 54 or 55 or 56 or 57 or 58 or 59 or 60.

In some embodiments, q is 0 or 2 or 3 or 4 or 5 or 6 or 7 or 8 or 9 or 10 or 11 or 12 or 13 or 14 or 15 or 16 or 17 or 18 or 19 or 20 or 21 or 22 or 23 or 24 or 25 or 26 or 27 or 28 or 29 or 30 or 31 or 32 or 33 or 34 or 35 or 36 or 37 or 38 or 39 or 40 or 41 or 42 or 43 or 44 or 45 or 46 or 47 or 48 or 49 or 50 or 51 or 52 or 53 or 54 or 55 or 56 or 57 or 58 or 59 or 60.

In some embodiments, the perovskite material is of the formula RₗA_{q}MₙXₚ, wherein

A is selected from organic cations, metal cations, inorganic cations and any combination of such cations;

R is selected from organic cations;

M is a metal cation or any combination of metal cations;

X is selected from anions and any combination of anions;

n is equal or between 1 to 60;

p is equal or between 1 to 60;

l is equal or between 1 to 60; and

q is equal or between 0 to 60.

In some embodiments, the perovskite material is of the above formulae, wherein each of R, A, M and/or X, independently, represents only one element (e.g., one anion), while in other embodiments, each of R, A, M and/or X, independently, represent more than one element.

In some embodiments, the perovskite material is of the formula RMₙXₚ or R₂MₙXₚ or R₃MₙXₚ or R₃MₙXₚ or R₅MₙXₚ or R₆MₙXₚ

wherein

R is selected from organic cations;

M is a metal cation or any combination of metal cations;

X is selected from anions and any combination of anions;

n is equal or between 1 to 60; and

p is equal or between 1 to 60.

In some embodiments, the perovskite material is of the formula RₗMₙXₚ or RₗM₂Xₚ or RₗM₃Xₚ or RₗM₄Xₚ or RₗM₅Xₚ or RₗM₆Xₚ

wherein

R is selected from organic cations;

M is a metal cation or any combination of metal cations;

X is selected from anions and any combination of anions;

p is equal or between 1 to 60; and

l is equal or between 1 to 60.

In some embodiments, the perovskite material is of the formula RₗMₙX or RₗMX₂ or RₗMX₃ or RₗMX₄ or RₗMX₅ or RₗMX₆

wherein

R is selected from organic cations;

M is a metal cation or any combination of metal cations;

X is selected from anions and any combination of anions;

n is equal or between 1 to 60; and

l is equal or between 1 to 60.

In some embodiments, the perovskite material is of the formula RMX₃ or RMX₄ or R₂MX₄ or R₃MX₅ or R₂A′MX₅ or RMX₃₋ₙX′ₙ or RR′MXX′, wherein

R and R′ are each independently selected from organic cations;

M is a metal cation or any combination of metal cations;

X and X′ are each independently selected from anions and any combination of anions; and

n is equal or between 0 to 3.

Repeating or multiple elements in any of the above perovskite formulae (e.g., R₂ or X₄ in R₂MX₄) may be the same or different. For example, A₂MX₄ may actually be of the structure RR′MXX′X″X′″.

The perovskite material formula comprising different elements (e.g., RR′) may appear in fragments (e.g., like metal alloy). For example, A₂MX₄ may actually be of the structure (AA′₍₁₋ₒ₎)₂ MₒM′₍₁₋ₒ₎ (XₒX′₍₁₋ₒ₎)₄, wherein 0≤o≤1. In other words any element, A and/or R and/or X and/or M, may be represented by more than one element (e.g., 2 or 3 or 4 or 5 elements), wherein the sum of these elements is multiplied by the number of times the elements appear in the perovskite material formula. For example, in a material of the formula AMX₃, the structure may be provided as (AₒA′₍₁₋ₒ₎)MₒM′₍₁₋ₒ₋ᵣ₎ M″ᵣ (XₒX′₍₁₋ₒ₎)₄, wherein 0≤o≤1 and 0≤o+r≤1.

In some embodiments, the perovskite material is of the formula R₄MX₁₀ or R₂R′₂MX₁₀ or R₂R′₂M₃X₁₀ or R₂R′₂M₃(X₍₁₋ₒ₎X′ₒ)₁₀

wherein

R is selected from organic cations;

M is a metal cation or any combination of metal cations; and

X is selected from anions and any combination of anions; and

O is equal to or between 0 to 1.

In some embodiments, the inorganic-organic perovskite is of the formula R₂(A)ₙ₋₁MₙX₃ₙ₊₁ (0<n), wherein

R is an organic cation;

A is an organic cation;

M is a metal;

X is a halogen.

In some embodiments, the organic cation is an ammonium or a derivative thereof. In some embodiments, in the organic cation is an organic cation selected from RNH₃, R₂NH₂, R₃NH, R₄N, RR′NH₂, RR′R″NH and RR′R″R′N, wherein each of the R groups may be selected independently as defined herein. In some embodiments, the cation is selected from RNH₃, RR′NH₂, R R′R″NH, NH₃RNH₃ and any combination thereof. In some embodiments, the cation is selected from RNH═R′, NH₂═R, RN═R′R′ R′═N═R, RR′N═R═NR″R′″, H₂N═R═NH₂ and RR′N═CHNR″R′″. In some embodiments, the cation is (H₂N═CHNH₂)⁺ or any combination thereof.

In some embodiments, the organic cation is an ammonium selected from RNH₃, R₂NH₂, R₃NH, R₄N, RR′NH₂, RR′R″NH and RR′R″R′″N, wherein at least one of R group is a carbonaceous group selected from C₁-C₂₀alkyl chains or C₁-C₂₀alkenyl chains or C₁-C₂₀alkynyl chains or any combination thereof. In some embodiments, the number of carbons in the aforementioned carbonaceous groups (e.g., alkyl) is 1 or 2 or 3 or 4 or 5 or 6 or 7 or 8 or 9 or 10 or 11 or 12 or 13 or 14 or 15 or 16 or 17 or 18 or 19 or 20.

In some embodiments, the organic cation is an ammonium cation that is selected from cations of the formula CH₃(CH₂)ₙNH₃, wherein 0≤n≤120.

In some embodiments, the organic cation is an ammonium cation selected from one or more of CH₃NH₃, CH₃CH₂NH₃, CH₃(CH₂)₂NH₃, CH₃(CH₂)₃NH₃, CH₃(CH₂)₄NH₃, CH₃(CH₂)₅NH₃, CH₃(CH₂)₆NH₃, CH₃(CH₂)₇NH₃, CH₃(CH₂)₈NH₃, CH₃(CH₂)₉NH₃, CH₃(CH₂)₁₀NH₃, CH₃(CH₂)₁₁NH₃, CH₃(CH₂)₁₂NH₃, CH₃(CH₂)₁₃NH₃, CH₃(CH₂)₁₄NH₃, CH₃(CH₂)₁₅NH₃, CH₃(CH₂)₁₆NH₃, CH₃(CH₂)₁₇NH₃, CH₃(CH₂)₁₈NH₃, CH₃(CH₂)₁₉NH₃ and CH₃(CH₂)₂₀NH₃.

In some embodiments, the anion is a halogen.

In some embodiments, the anion is selected from F, Cl, Br, I, At and any combination thereof.

In some embodiments, the anion is selected from Br, I and any combination thereof.

In some embodiments, the metal is Pb.

In some embodiments, the perovskite material is of the formula R₂(CH₃NH₃)ₙ₊₁MₙX₃ₙ₊₁ wherein

A is selected from organic cations, metal cations or any combination of such cations;

R is selected from organic cations;

M is a metal cation or any combination of metal cations;

X is selected from anions and any combination of anions;

n is equal or between 0 to 3.

In some embodiments, the organic-inorganic perovskite is of the formula (R)₂(CH₃NH₃)ₙ₋₁Pb(IₓBr₁₋ₓ)₃ₙ₊₁,

X is equal to or is between 0 and 1; and

n is equal to or is between 1 and 60.

In some embodiments, R is octylammonium.

In some embodiments, R is decylammonium.

In some embodiments, R is octadecylammonium.

In some embodiments, n is 1 or 2 or 3 or 4 or 5 or 6 or 7 or 8 or 9 or 10 or 11 or 12 or 13 or 14 or 15 or 16 or 17 or 18 or 19 or 20 or 21 or 22 or 23 or 24 or 25 or 26 or 27 or 28 or 29 or 30 or 31 or 32 or 33 or 34 or 35 or 36 or 37 or 38 or 39 or 40 or 41 or 42 or 43 or 44 or 45 or 46 or 47 or 48 or 49 or 50 or 51 or 52 or 53 or 54 or 55 or 56 or 57 or 58 or 59 or 60.

In some embodiments, the organic-inorganic perovskite is of the formula (C₈H₁₇NH₃)₂(CH₃NH₃)₂Pb₃(I)₁₀ or of the formula (CH₁₇NH₃)₂(CH₃NH₃)₂Pb₃(Br)₁₀ or of the formula (C₁₂H₂₅NH₃)₂(CH₃NH₃)₂Pb₃(I)₁₀ or of the formula (C₁₂H₂₅NH₃)₂(CH₃NH₃)₂Pb₃(Br)₁₀ or of the formula (C₁₈H₂₇NH₃)₂(CH₃NH₃)₂Pb₃(I)₁₀ or of the formula (C₈H₂₇NH₃)₂(CH₃NH₃)₂Pb₃(Br)₁₀.

In some embodiments, the perovskite material is any one of the lead containing perovskite materials recited herein.

In some embodiments, the perovskite nanoparticles of the invention are surface associated with a plurality of ligand molecules, the association being on a surface region thereof, which may be any one surface region or the complete surface of the nanoparticles. In some embodiments, the ligand molecules bind to specific lattice sites on a surface region or complete region of the nanoparticle. In some embodiments, the ligand molecules comprise at least one ligand types.

In some embodiments, at least a portion of the plurality of ligand molecules consists organic ligands. In some embodiments, the ligand molecules are oleic acid.

In some embodiments, the ligand molecule is an ammonium ligand. In some embodiments, the ligand molecules are octylammonium. In some embodiments, the ligand molecules are decylammonium. In some embodiments, the ligand molecules are octadecylammonium.

The present invention provides in another aspect a colloidal perovskite nanoparticle, wherein said nanoparticle is a nanorod or nanocube. In some embodiments, the perovskite material comprises a halide.

The present invention provides in another aspect a nanoparticle, wherein said nanoparticle is a nanorod or nanocube, the nanoparticle comprising at least one perovskite material, wherein the nanoparticle is a colloidal nanoparticle.

In another aspect, the invention provides a population of nanoparticles comprising nanoparticles according to the invention. In another aspect, the invention provides a population of nanoparticles consisting nanoparticles of the invention.

In some embodiments, the population of nanoparticles being characterized by a uniform (or narrow) size distribution.

In another aspect, the invention provides a composition comprising a population of nanoparticles, said population comprising a plurality of perovskite nanorods, nanocubes or a combination thereof, each of said perovskite nanoparticles consisting a perovskite material and having a long axis length of at most 800 nm.

In another aspect, the invention provides a population of perovskite nanoparticles, said population consisting perovskite nanoparticles selected from nanorods and/or nanocubes and a combination thereof.

In some embodiments, the populations of perovskite nanoparticles of the invention are provided dispersed in a medium.

In another aspect, the invention provides as-prepared colloidal perovskite nanoparticles, wherein said nanoparticles are nanorods and/or nanocubes or a combination thereof.

In another aspect, the invention provides pure or essentially uniform (in shape, size, etc.) population of colloidal perovskite nanoparticle, said nanoparticles being selected from nanorods and nanocubes.

As used herein, populations of perovskite nanoparticles that are “essentially uniform” are populations that at least 85%, 86%, 87%, 88%, 89%, 90%, 91%, 92%, 93%, 94%, 95%, 96%, 97%, 98%, 99% or 100% of the nanoparticles in the populations are of the same type. In other words, the nanoparticles are of the same size distribution, same constitution, same shape, same material composition, being all nanorods, and/or all nanocubes, etc. In some embodiments, each population consists a uniform selection of nanoparticles. A “narrow distribution” of any one population of nanoparticles, thus refers to a population that is essentially uniform, as defined.

In another aspect the invention provides a medium comprising perovskite nanoparticles selected from nanorods or nanocubes; the medium having at least one of the following improved characteristics:
1. It comprises a high yield of perovskite nanorods, nanocubes or a combination thereof;
2. It comprises perovskite nanorods or nanocubes having a narrow distribution of shapes;
3. It comprises perovskite nanorods or nanocubes having a narrow distribution of sizes;
4. It comprises perovskite nanorods or nanocubes having a narrow distribution of aspect ratios;
5. It comprises a population of perovskite nanorods or nanocubes having controlled aspect ratios.
6. It comprises a population of perovskite nanorods or nanocubes having high quantum efficiency (high quantum yield).

As noted above, according to some aspects of the invention, a medium may comprise “as-prepared perovskite nanoparticles”. In other words, the nanoparticles comprised in the medium are the crude nanorods and/or nanocubes obtained directly in the medium in which the process for their preparation is carried out, with no (or substantially no) further purification steps (e.g., size selective precipitation, purification, ligand exchange), thereby providing a crude sample (solution/dispersion) of nanoparticles. The “medium of nanoparticles” comprising one or more nanoparticles (nanocrystals), typically a plurality of nanoparticles, wherein said nanoparticles are nanorods, nanocubes or a combination thereof, said medium may be in a form selected from a solution (or colloidal solution), a suspension or a dispersion of nanorods and/or nanocubes. In some embodiments, the medium is a liquid medium. In some embodiments, the liquid medium is a mixture of one or more organic solvents (liquids), which may or may not further contain solubilized materials. In some embodiments, the medium is an organic solution. In some embodiments, the medium is an inorganic solution. In some embodiments, the medium is aqueous solution. In some embodiments, the medium is a solid medium, in the form of a carrier powder or solid or in the form of a polymer or a martial matrix in which the nanoparticles are carried, encapsulated, embedded, encased or otherwise contained.

In some embodiments, the medium is an organic solvent selected from dimethylformamide (DMF) and octadecene.

Thus, the medium comprises nanoparticles, wherein the nanoparticles are nanorods, nanocubes or a combination thereof, said medium may be the direct product of a synthetic process of the perovskite material, being by chemical synthesis (in solution) or colloidal synthesis (growth).

In some embodiments, the medium comprises perovskite nanorods having a narrow distribution of sizes, all being rods in shape; namely, the vast majority of the nanorods being of a size characterized by a minimal deviation from a certain size (measured as the length of long axis and/or the short axis) or aspect ratio.

In some embodiments, the medium may further comprise other nanoparticles that are not perovskite nanorods. In such cases, at least 70% of the nanoparticles are nanorods. In further embodiments, at least 80% of the nanoparticles are nanorods. In further embodiments, at least 90% of the nanoparticles are nanorods. In other embodiments, at least 95% of the nanoparticles are nanorods; and in other embodiments, between 95 and 98% of the nanoparticles are nanorods.

Nanoparticles populations characterized by “uniform” or “narrow” size distribution are populations according to the invention which dimensions (lengths of long axis and/or short axis) exhibit size deviations from a measureable or calculated mean value. In some embodiments, the size deviation is ±30% from their mean value, ±20%, ±10%, ±5%, ±4%, ±3%, ±2%, ±1%, ±0.5%, ±0.4%, ±0.3%, ±0.2% or ±0.1% from their mean value.

Similarly, the deviation may be from a mean aspect ratio.

The medium of the invention may comprise a high yield of single crystalline nanorods and/or nanocubes. In other words, in a medium, the majority of nanorods are single crystalline nanorods/nanocubes with only a small portion of the nanorods/nanocubes or none of them being in an amorphous or polycrystalline or polymorphic form (phase).

In some embodiments, at least 70% of the nanoparticles, i.e., nanorods or nanocubes, are single crystals. In further embodiments, at least 80%, at least 90%, at least 95%, at least 96%, at least 97%, at least 98% or at least 99% of the nanorods or nanocubes are single crystals. In additional embodiments, between 95 to 99% of the nanorods or nanocubes are single crystals.

The perovskite nanoparticles of the invention have a high quantum efficiency.

In some embodiments, the quantum efficiency is at least 5%. In some embodiments, the quantum efficiency is at least 10%. In some embodiments, the quantum efficiency is at least 15%. In some embodiments, the quantum efficiency is at least 20%. In some embodiments, the quantum efficiency is at least 25%.

In another aspect of the invention there is provided a use of a nanoparticle of the invention, as defined, in the preparation of a suspension, dispersion or solution.

In another aspect, the invention provides a process for preparing or manufacturing perovskite nanoparticles, said nanoparticles being nanorods, nanocubes or combinations thereof, according to the invention, the process comprising:
treating a solution comprising precursors of at least one perovskite material under conditions allowing growth of the perovskite nanoparticles.

In some embodiments, the process further comprises:
obtaining a solution of a precursor of at least one perovskite material and treating same under suitable conditions.

In some embodiments, the step of obtaining a solution comprising precursors of at least on perovskite material comprises:
obtaining one or more metal precursors solution, optionally containing an anion precursor of the perovskite material; and/or
obtaining one or more organic cation precursor solution, optionally containing an anion precursor of the perovskite material; and/or
optionally obtaining one or more anion precursors solution; and/or
optionally obtaining one or more ligand precursors solution, optionally containing an anion precursor of the perovskite material.
optionally contacting the metal precursors solution with the cation precursors solution and optionally with the anion precursors solution of the perovskite material to afford a mixture.

In some embodiments, the metal precursor solution comprises an organic solvent, the organic solvent being dimethylformamide. In some embodiments, the metal precursor solution comprises PBI₂ and/or PbBr₂.

In some embodiments, the organic cation precursor solution comprises an organic solvent, the organic solvent being dimethylformamide.

In some embodiments, the ligand precursor solution comprises an organic solvent, the organic solvent being octadecene. In some embodiments, the ligand precursor solution comprises octylammonium iodide and/or decylammonium iodide and/or octadecylammonium iodide and/or oleic acid.

In some embodiments, one or more of the precursors solutions additionally contains a synthesis aiding agent. In some embodiments, the one or more organic cation precursors solution additionally contains a synthesis aiding agent. In some embodiments, the at least one another organic cation precursors solution additionally contains a synthesis aiding agent. In some embodiments, the synthesis aiding agent is oleic acid.

In some embodiments, the process for making the nanoparticles of the invention includes one or more organic cation precursors solution. In some embodiments, one of the solutions or combinations of solutions direct elongated growth of the nanoparticles. In some embodiments, one of the solutions or combinations of solutions direct cubic growth of the nanoparticles. In some embodiments, the synthesis of the nanoparticles includes a single type of organic cation precursors, in a solution.

In some embodiments, the synthesis of the nanoparticles includes two or more organic cation precursors in two or more separate solutions. In some embodiments, one of the two or more organic cation precursors solutions contains an organic cation which binds only to certain facets and/or only to the surface of the nanoparticles, while the other of the two or more organic cation precursors solutions contains an organic cation that binds to other facets or lattice sites or does not have a preference towards sites of attachment.

In some embodiments, the process utilizes one or more organic cation precursors solution or solutions. In some embodiments, the process utilizes two or more organic cation precursors solution or solutions, wherein one or more organic cation precursor comprises a long carbon chain, e.g. octylamine, while the another organic cation comprises a short carbon chain e.g., methylamine. In some embodiments, the organic cation is an alkylamine, wherein the amine is covalently bonded to an alkyl group having between 1 and 25 carbon atoms (C₁-C₂₅amine). In some embodiments, the alkylamine is selected from C₁-alkylamine, C₂-alkylamine, C₃-alkylamine, C₄-alkylamine, C₅-alkylamine, C₆-alkylamine, C₇-alkylamine, C₈-alkylamine, C₉-alkylamine, C₁₀-alkylamine, C₁₁-alkylamine, C₁₂-alkylamine, C₁₃-alkylamine, C₁₄-alkylamine, C₁₅-alkylamine, C₁₆-alkylamine, C₁₇-alkylamine, C₁₈-alkylamine, C₁₉-alkylamine, C₂₀-alkylamine, C₂₁-alkylamine, C₂₂-alkylamine, C₂₃-alkylamine, C₂₄-alkylamine and C₂₅-alkylamine.

In some embodiments, the organic cation precursor is selected from octylamine iodide, octylamine bromide, methylamine iodide, methylamine bromide, decylamine iodide, decylamine bromide, octadecylamine iodide and octadecylamine bromide.

As used herein, the conditions “allowing growth of perovskite nanoparticles” mainly include mixing the components of the reaction at room temperature or at a temperature not higher than 200° C.

In some embodiments, the process is carried out at room temperature (RT), i.e. at a temperature between 20° C. and 30° C.

In some embodiments, the process is carried out at a temperature between 20° C. and 100° C.

In some embodiments, the process is carried out at a temperature between 50° C. and 100° C. In some embodiments, the process is carried out at a temperature between 50° C. and 90° C. In some embodiments, the process is carried out at a temperature between 50° C. and 80° C. In some embodiments, the process is carried out at a temperature between 60° C. and 80° C., 60° C. and 85° C., 60° C. and 90° C., 60° C. and 70° C., 60° C. and 75° C., 70° C. and 90° C., 70° C. and 85° C., 70° C. and 80° C., 80° C. and 90° C. or between 80° C. and 85° C.

In some embodiments, the process is carried out at or about 80° C.

In some embodiments, the process involves heating, e.g., to above RT. In some embodiments, the heating is to a temperature between RT and 200° C. In some embodiments, the heating is to a temperature between RT and 150° C. In some embodiments, the heating is to a temperature between RT and 125° C. In some embodiments, the heating is to a temperature between RT to 100° C. In some embodiments, the heating is to a temperature between RT to 80° C.

In another aspect, the invention provides a matrix comprising nanoparticles of the invention. In some embodiments, the nanoparticles are embedded in the matrix material. In some embodiments, the nanoparticles are deposited onto the matrix surface. In some embodiments, the nanoparticles are formed into a film, wherein the film material is optionally in a matrix form. Thus, the invention further provides a film embedding or holding or associating with a plurality of nanoparticles according to the invention.

In another aspect, the invention provides an element, wherein a surface region of the element comprises or is associated with a plurality of nanoparticles of the invention. In some embodiments, the surface region of the element is associated with a film comprising nanoparticles of the invention.

In another aspect of the invention, there is provided a device, the device comprising an element or a film or a layer or nanoparticles according to the invention. In some embodiments, the device is an optoelectronic device.

In some embodiments, the device is one or more of the following: a diode, a photodiode, a transmitter, a laser, a gain device, an amplifier, a switch, a marker, a bio-marker, a display, a large area display, liquid-crystal displays (LCDs), a detector, a photodetector, a sensor, a light emitting diode, a lighting system and a solar cell.

In some embodiments, the device is a solar cell.

In some embodiments, the device is a light emitting diode.

The invention further provides a perovskite nanoparticle selected from a nanorod and a nanocube, the nanoparticle having a length of between 3 and 200 nm.

The invention also provides a perovskite nanoparticle selected from a nanorod and a nanocube, the nanoparticle having an aspect ratio of between 1 and 100.

In some embodiments, the nanoparticle has an aspect ratio of between 1 and 100.

In some embodiments, the nanorod is of a perovskite material comprising at least one organic-inorganic perovskite.

In some embodiments, the perovskite is or comprises a lead halide.

In some embodiments, the nanoparticle has an aspect ratio of between 1 and 100, the nanoparticle being of a perovskite material comprising lead halide.

In some embodiments, the nanoparticle has a length of between 3 and 200 nm.

The invention further provides a perovskite nanoparticle selected from a nanorod and a nanocube, the nanoparticle having a length of between 3 and 200 nm, the nanoparticle being of a perovskite material comprising lead halide.

In some embodiments, the organic-inorganic perovskite is of the formula R₂(A)ₙ₋₁MₙX₃ₙ₊₁ (1<n), wherein R is an organic cation, A is an organic cation, M is a metal and X is a halogen.

In some embodiments, the nanoparticle has a length of between 3 and 20 nm.

In some embodiments, the halide is an anion selected from I, Br, F, Cl, At and a combination thereof.

In some embodiments, the perovskite comprises at least one organic cation selected from ammonium cations.

In some embodiments, the ammonium cation is of the formula CH₃(CH₂)NH₃, wherein 0≤n≤120.

In some embodiments, the nanoparticles are surface associated with ligand molecules.

In some embodiments, wherein at least a portion of the ligand molecules is oleic acid.

The invention further provides a lead halide perovskite nanoparticle selected from nanorods and nanocubes.

The invention further provides a population of nanoparticles comprising nanoparticles according to the invention.

Also provided is a population of nanoparticles consisting nanoparticles according to the invention.

In some embodiments, the population comprises or consists nanorods or nanocubes.

In some embodiments, the population is characterized by a uniform or narrow size distribution.

In some embodiments, the population is in the form of a suspension or a dispersion.

The invention further provides a film comprising a population of nanoparticles according to the invention.

The invention further provides an element comprising a surface region coated by a film according to the invention.

A device is further provided that comprises an element according to the invention, the device being selected from a photovoltaic cell, a laser, a light emitting diode, a solar cell and an optical sensor.

A use is provided of a nanoparticle according to the invention in the preparation of a suspension, dispersion or solution.

A process is also provided for preparing perovskite nanoparticles, the nanoparticles being selected from perovskite nanorods and nanocubes, the process comprising treating a solution comprising precursors of at least one perovskite material under conditions allowing growth of the perovskite nanoparticles.

A further process is provided for preparing perovskite nanoparticles according to the invention, the process comprising treating a solution comprising precursors of at least one perovskite material under conditions allowing growth of the perovskite nanoparticles.

In some embodiments, the process further comprises obtaining a solution of precursors of at least one perovskite material.

In some embodiments, the process further comprises obtaining one or more metal precursors solution, optionally containing an anion precursor of the perovskite material.

In some embodiments, the process further comprises obtaining one or more organic cation precursors solution, optionally containing an anion precursor of the perovskite material.

In some embodiments, the process further comprises two or more organic cation precursors solutions, wherein one or more organic cation precursor comprises a long carbon chain, while another organic cation comprises a short carbon chain.

In some embodiments, the process further comprises obtaining one or more anion precursors solution containing an anion precursor of the perovskite material.

In some embodiments, the process further comprises obtaining one or more ligand precursors solution, optionally containing an anion precursor of the perovskite material.

In some embodiments, the process further comprises contacting the metal precursors solution with the organic cation precursors solution and optionally with the anion precursors solution of the perovskite material to afford a mixture.

In some embodiments, the metal precursor solution comprises at least one lead halide.

In some embodiments, the lead halide is PBI₂ and/or PbBr₂.

In some embodiments, the metal precursor solution comprises at least one organic solvent.

In some embodiments, the organic cation precursor solution comprises at least one organic cation precursor selected from octylamine iodide, octylamine bromide, methylamine iodide, methylamine bromide, decylamine iodide, decylamine bromide, octadecylamine iodide and octadecylamine bromide.

In some embodiments, the conditions allowing growth of the perovskite nanoparticles comprise mixing the solution at room temperature or at a temperature below 200° C.

In some embodiments, the temperature is below 100° C., below 90° C. or is about 80° C. (between 75 and 85° C.).

In some embodiments, the process comprises:
1) obtaining a solution of at least one lead halide;
2) obtaining a solution of at least one amine selected from methylamine iodide or methylamine bromide; and
3) mixing solutions (1) and (2) under conditions permitting formation of the nanoparticles.

In some embodiments, the process comprises:
1) obtaining a solution of PbI₂ or PbBr₂ in a solvent;
2) obtaining a solution of methylamine iodide or methylamine bromide in a solvent;
3) obtaining a solution of octylammonium iodide (OAI), oleic acid (OAc) and octadecene;
4) mixing solutions (1), (2) and (3) under conditions permitting formation of the nanoparticles.

In some embodiments, the process is carried out at room temperature.

In some embodiments, the process is carried out at a temperature below 200° C.

In some embodiments, the temperature is below 100° C., below 90° C. or is about 80° C.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 provides TEM images and inset FFTs of the nanorods made from various halide compositions according to the invention.

FIGS. 2A-D are HRTEM images of the nanorods shown in FIG. 1.

FIGS. 3A-B provide: FIG. 3A—XRD of the various nanorods compositions. The wide peaks support the TEM observation of accepting nano-sized particles. FIG. 3B provides an electron diffraction image of (CH₁₇NH₃)₂(CH₃NH₃)₂Ph₃I₁₀ nanorods.

FIGS. 4A-D provide: FIG. 4A an image of the emitting nanorods dispersions composed of various halide mixtures. FIG. 4B provides absorbance spectra of the 2D perovskite nanorods of various halides compositions. FIG. 4C provides PL spectra of the 2D perovskite nanorods; and FIG. 4D provides PL-QY and band gap energies measured and calculated by Tauc plot of the perovskite nanorods compositions.

FIGS. 5A-D provide Tauc plots of the various OMHP-nanorod compositions: FIG. 5A—(C₈H₁₇NH₃)₂(CH₃NH₃)₂Pb₃I₁₀, FIG. 5B—(C₈H₇NH₃)₂(CH₃NH₃)₂Pb₃(IₓBr₁₋ₓ)₁₀, (I>Br), FIG. 5C—(C₈H₇NH₃)₂(CH₃NH₃)₂Pb₃(IₓBr₁₋ₓ)₁₀, (I<Br), and FIG. 5D—(C₈H₁₇NH₃)₂(CH₃NH₃)₂Pb₃Br₁₀.

FIGS. 6A-F provide TEM images of MAPbI₃ QDs/NRs prepared at various OAI/OAc ratios: FIG. 6A—100% OAc; FIG. 6B—OAI/OAc=0.075. FIG. 6C—OAI/OAc=0.186. FIG. 6D—OAI/OAc=0.250; the two figures are taken from the same sample in different areas; FIG. 6E—100% OAI. FIG. 6F—schematic illustration of the suggested NRs formation mechanism; the OAI and the OAc are presented schematically in the figure, while the black dots represent the methylammonium and the brown rhombus represent the PbI₂.

FIG. 7 provides HRTEM images of the NPs made of octyl/dodecyl/octadecyl ammonium iodide. Each couple of two vertical images presents particles of the same ligand, while the magnification is larger at the bottom image (see the scale bar).

FIGS. 8A-D provide: FIG. 8A—absorption spectra of the particles prepared using octyl/dodecyl/octadecyl ammonium iodide. FIG. 8B—PL spectra of the particles. FIG. 8C—an image of the particles under white light. FIG. 8D—an image of the particles under UV light (λ=254 nm).

FIG. 9 provides HRTEM images of the NPs made of octyl/dodecyl/octadecyl ammonium bromide. Each couple of two vertical images presents particles of the same ligand, while the magnification is larger at the bottom image (see the scale bar).

FIGS. 10A-D provide: FIG. 10A—absorption spectra of particles prepared using octyl/dodecyl/octadecyl ammonium bromide. FIG. 10B—PL spectra of the particles prepared using octyl/dodecyl/octadecyl ammonium bromide. FIG. 10C—an image of the particles under white light. FIG. 10D—an image of the particles under UV light (λ=254 nm).

### DETAILED DESCRIPTION OF EMBODIMENTS

This invention provides facile low temperature synthesis of 2D perovskite nanorods in the structure (C₈H₁₇NH₃)₂(CH₃NH₃)₂Pb₃(IₓBr₁₋ₓ)₁₀, 0>x>1. The NRs were characterized by XRD, ED, and FFT analysis. The absorbance and the PL of the NRs show a shift to higher energies compared with the bulk materials. In addition, changing the halide composition enables tunability of the NRs band gap. Various ligands ratios were studied and analyzed by high-resolution transmission electron microscopy (HR-TEM), which assisted in revealing the formation mechanism of these novel 2D perovskite NRs.

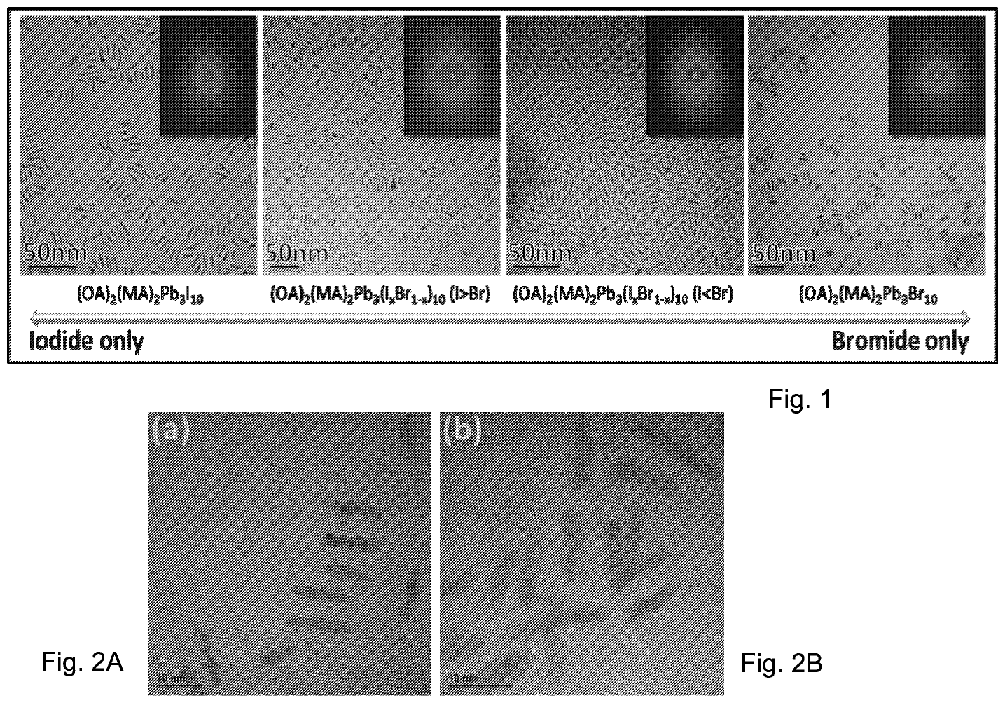

FIG. 1 presents TEM images of the synthesized 2D perovskite NRs of the structure R₂(CH₃NH₃)_{n□1}MₙX₃ₙ₊₁ where (R═octylammonium, OA, being C₈H₁₇NH₃, CH₃NH₃=MA, M=Pb, X=I, Br, 0<n<3). The halide composition did not affect the shape and the size of the nanorods; the average size of the nanorods was 2.25 nm 0.3 nm (width) and 11.36 nm±2.4 nm (length). The crystallographic structure of the NRs was analyzed using FFT as indicated in the insets provided in the images.

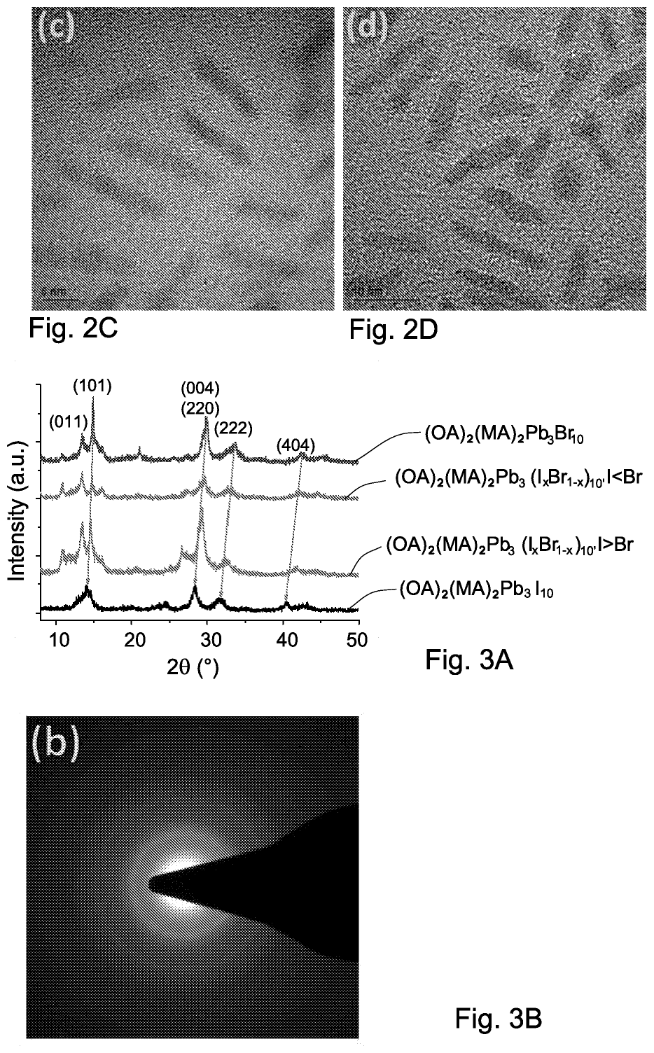

HRTEM images of the nanorods are shown in FIGS. 2A-D.

Table 1 shows the d-spacing values which were taken from the FFT analysis and the corresponding Miller indices for the various compositions. The crystallographic characterizations show that the perovskite NRs have tetragonal structure. It can be observed that the introduce of the Br ions into the perovskite structure changes the lattice parameters from a=b=8.856 Å, c=12.674 Å for (OA)₂(MA)₂Pb₃I₁₀ to a=b=8.611 Å, c=12.234 Å for (OA)₂(MA)₂Pb₃(IₓBr₁₋ₓ)₁₀ (I>Br), a=b=8.484 Å, c=12.294 Å for (OA)₂(MA)₂Pb₃(IₓBr₁₋ₓ)₁₀ (I<Br) and a=b=8.474 Å, c=11.943 Å for pure (OA)₂(MA)₂Pb₃Br₁₀ as described previously for bulk perovskite where the lattice parameter changes due to the smaller ionic radius of the Br⁻ compared with I⁻.

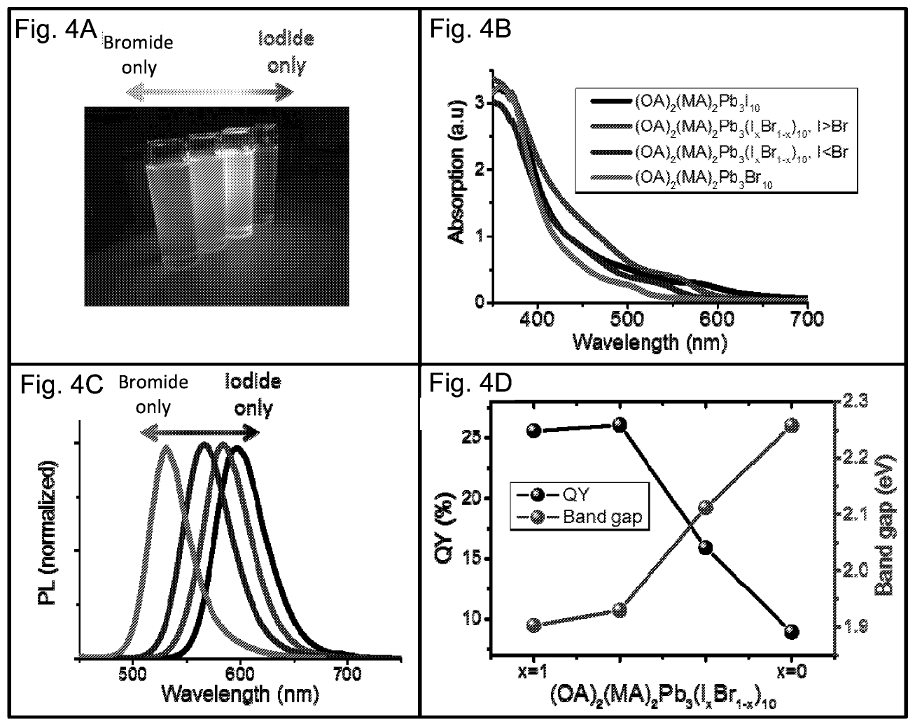

The optical characterizations of the 2D perovskite NRs are presented in FIG. 4, including absorbance and PL; FIGS. 4B and 4C, respectively. The absorbance spectra of the various compositions are not similar to the absorbance of the bulk perovskite with the same compositions. MAPbI₃ and MAPbBr₃ bulks absorb until ˜800 nm and until ˜550 nm, respectively, while the (OA)₂(MA)₂Pb₃I₁₀ NRs and (OA)₂(MA)₂Pb₃Br₁₀ NRs absorb only until ˜650 nm and ˜530 nm, respectively (FIG. 4B).

TABLE 1
crystallographic data of the different NRs compositions, extracted from
FFTs (see FIG. 1 inset). C₈H₁₇NH₃ = OA, CH₃NH₃ = MA

| | | (OA)₂(MA)₂Pb₃(IₓBr₁₋ₓ)₁₀, | | (OA)₂(MA)₂Pb₃(IₓBr₁₋ₓ)₁₀, | | | |
|---|---|---|---|---|---|---|---|
| (OA)₂(MA)₂Pb₃I₁₀ | | I > Br | | I < Br | | (OA)₂(MA)₂Pb₃Br₁₀ | |
| d-spacing | | d-spacing | | d-spacing | | d-spacing | |
| (Å) | (hkl) | (Å) | (hkl) | (Å) | (hkl) | (Å) | (hkl) |
| 1.81 | (404) | 2.55 | (312) | 1.82 | (404) | 1.76 | (226) |
| 2.55 | (312) | 3.15 | (004) | 2.56 | (312) | 2.54 | (312) |
| 2.80 | (310) | 3.12 | (220) | 3.18 | (004) | 3.12 | (220) |
| 3.15 | (004) | | | | | 3.17 | (004) |

The difference in the absorbance is attributed to two main contributions. The first is related to the use of octylammonium as a ligand in the NRs synthesis. The octylammonium is a larger cation than the methylammonium and cannot incorporate into the perovskite structure. Therefore, the octylammonium is attached through its alkyl chain to the perovskite and limited the crystal growth in this direction (Additional details regarding the growth mechanism of these NRs are discussed below). Since the perovskite growth is limited, the perovskite NRs are formed in the 2D perovskite structure which implies a shift in the absorbance and PL to shorter wavelength (higher energies) and hence to larger band gaps.

The second contribution is related to the halide exchange when introducing Br into the (OA)₂(MA)₂Pb₃I₁₀ NRs. The Br(4p) orbitals with the Pb(6s) orbitals determined the absorbance peak, which is related to the valence band. The conduction band of PbI₂ is composed of Pb(6p) orbitals, while its valence band composed of Pb(6s) orbitals and I(5p) orbitals. It was shown that the transitions in PbI₂ are similar to the transitions in MAPbIₓBr₃₋ₓ (0>x>3). Further, the energy level of Br(4p) orbitals is lower in energy than Pb(6s) orbitals; therefore, the peak position of (OA)₂(MA)₂Pb₃(IₓBr₁₋ₓ)₁₀, 0>x>1 is influenced and shifted to higher energy. This shift can be observed in FIGS. 4B and 4C when the increase in the Br concentration shifts the absorbance and the PL to higher energies. FIG. 4A shows the visual emission from the (OA)₂(MA)₂Pb₃(IₓBr₁₋ₓ)₁₀ NRs in various compositions (0>X>1), from pure iodide to pure bromide. It can be observed that the pure (OA)₂(MA)₂Pb₃I₁₀ has a red emission supporting the PL and the Eg measurements.

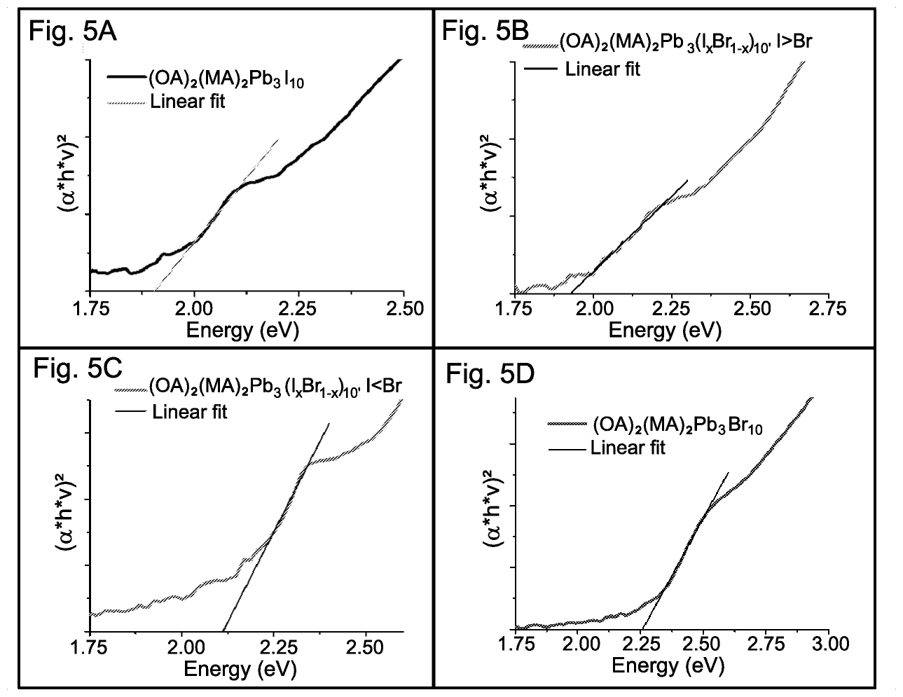

Tauc plots were recorded for the NRs samples to calculate the energy band gaps (E_{g}) of these nano materials. Tauc plots are given in FIG. 5, and their values are presented in FIG. 4D. As in the case of the bulk methylammonium lead halide perovskite, the Br concentration increases the materials' E_{g}. However, the 2D perovskite NRs E_{g} are in the range of 1.9 eV-2.26 eV with variation from the bulk methylammonium lead halide perovskite.

The PL-QY of the various NRs compositions is presented in FIG. 4D. The PL-QY is close to 30% for the (OA)₂(MA)₂Pb₃I₁₀ NRs and for the (OA)₂(MA)₂Pb₃(IₓBr₁₋ₓ)₁₀ (I>Br) NRs. When the Br concentration is increased, the PL-QY decreased. Feldmann et al. have reported similar PL-QY for the perovskite nanostructures they studied. PL-QY of 20% was demonstrated for MAPbBr₃ nanoparticles synthesized in a medium of alkyl-amine that controls the particle growth, and Hassan et al. measured 20% QY for 2D perovskite NPs.

The main factor influencing the formation of the NRs is the organic moieties present in the synthesis. Three organic molecules are used in the synthesis, methylammonium iodide/bromide (MAI/MABr), octylammonium iodide (OAI) and oleic acid (OAc). The long chain of the octylammonium iodide cannot be incorporated into the perovskite crystal. Instead it attached to specific sites on the perovskite surface inhibiting the growth in a particular direction. In addition, the presence of OAc in the synthesis solution plays a role in the formation of the NRs as discussed below. To elucidate the formation mechanism of these 2D perovskite NRs, the ratio of OAc to OAI was studied. Different molar ratios of ligands (OAI and OAc) were studied while keeping all other conditions constant (see Experimental Section).

The ratio of the OAI/OAc for the NRs discussed in this work is OAI/OAc=0.186. Therefore, ratios of 100% OAc, OAI/OAc=0.075 (lower than the standard ratio), OAI/OAc=0.250 (higher than the standard ratio) and 100% OAI were investigated.

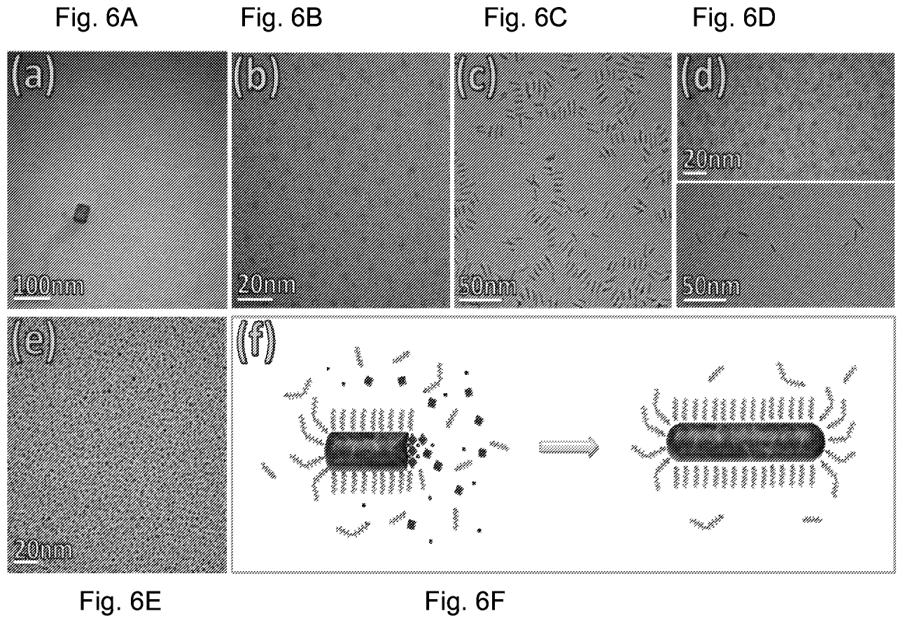

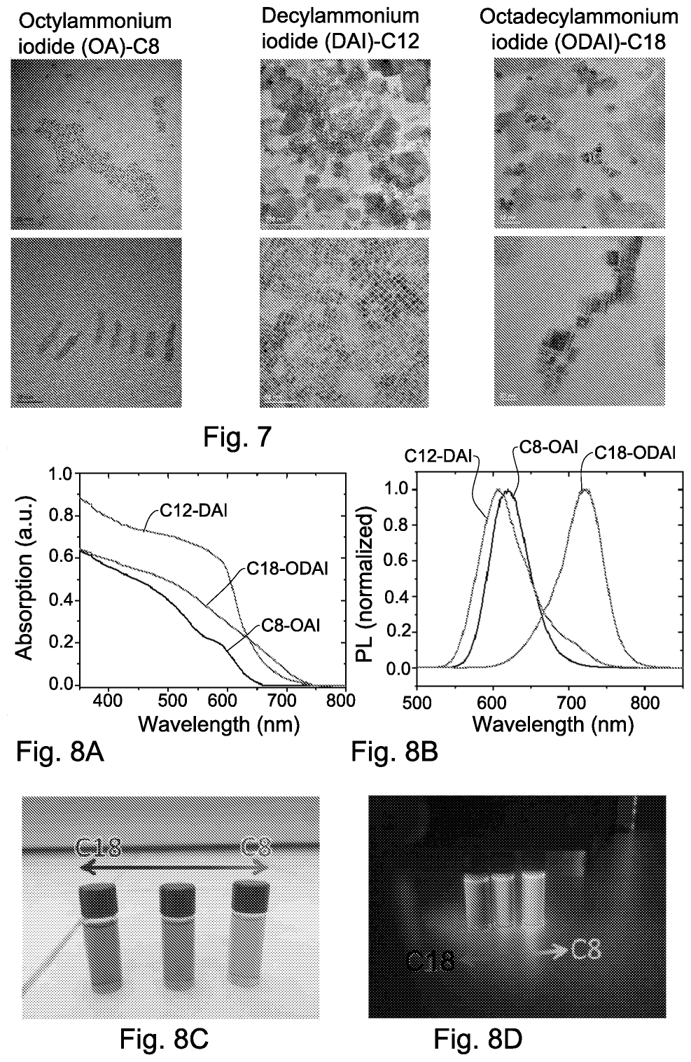

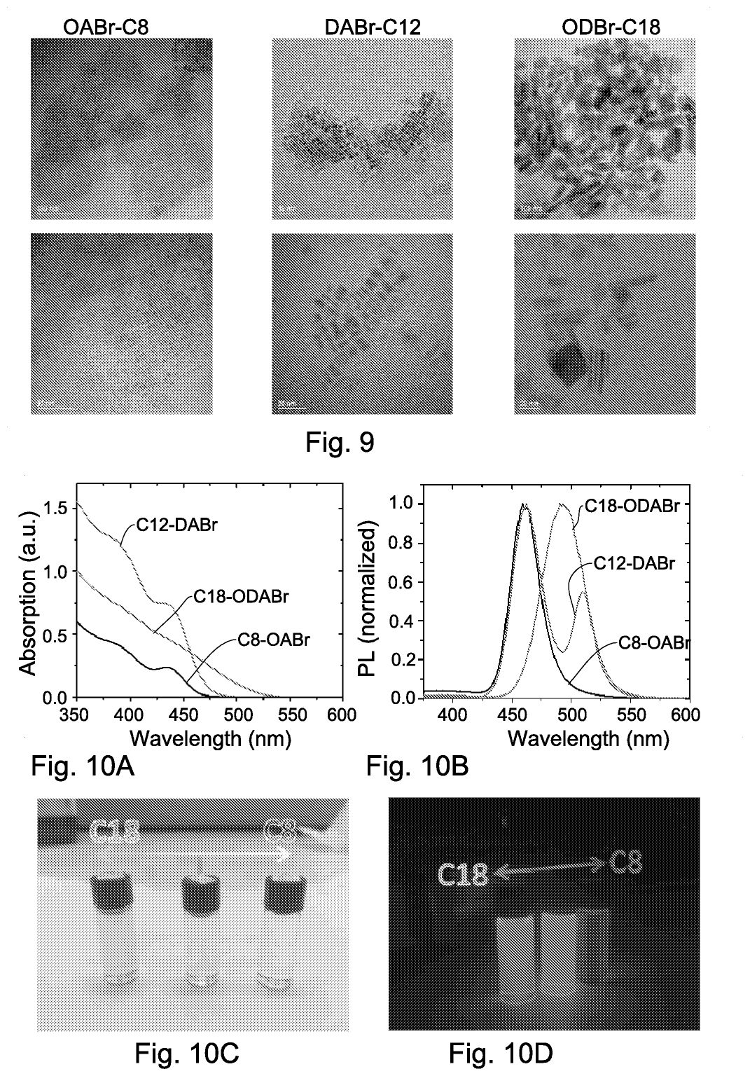

TEM micrographs were recorded for the OAI/OAc ratios (FIGS. 6A-E). For 100% OAc (without OAI in the solution), there was no indication of the formation of QDs; the perovskite was formed as a bulk which precipitated to the bottom of the vial (FIG. 6A shows empty TEM grid). For OAI/OAc=0.075, the formation of QDs was observed, although their concentration was low (FIG. 6B). Where higher ratios were studied, e.g. OAI/OAc=0.250, mixed QDs and NRs were observed, indicated in FIG. 6D; and for 100% OAI, a high concentration of QDs was observed (FIG. 6E).

These results propose the following mechanism. At 100% OAc, no QDs were observed, which means that the OAc could not inhibit the perovskite growth. However, at 100% OAI, a high concentration of QDs was observed, suggesting that the OAI inhibits perovskite growth and attached strongly to the perovskite surface. The presence of iodide in the OAI assisted in the attachment of this alkyl chain to the QDs/NRs perovskite surface. When varying the ratio to 0.250 (excess of OAI relative to the standard), QDs and NRs are formed, indicated by the two images in FIG. 4D which were taken from the same sample. For a ratio of 0.075 (excess of OAc relative to the standard), the formation of NRs were rare. Therefore, it can be concluded that the OAI is attached to the NRs surface, while the OAc has an important role by shaping these QDs into NRs. The OAI attachment is much stronger to the NRs surface than that of the OAc since it fills the octahedral hole. The NRs are formed by the addition of monomers along specific axis, while the other axes length are blocked by high affinity ligands absorbed to the surface (FIG. 6F). The presence of the two ligands is essential for the formation of the NRs. As discussed, the OAI has higher affinity to the perovskite surface than the OAc, so that for OAI/OAc=0.075, there are not enough OAI ligands to allow the formation of NRs (and even the QDs formation is low). When the ratio was increased to OAI/OAc=0.250 with an excess of OAI, some NRs were formed with a high concentration of QDs due to the stabilization of the QDs by the OAI, but the low concentration of OAc results in the formation of few NRs. Therefore, pure NRs formation is achieved only when there is a balanced ratio of OAI/OAc=0.186. On one hand, there is enough OAI to stabilize the NRs perovskite surface, and on the other hand, enough OAc to balance the growth into NRs shape.

### CONCLUSIONS

This invention provides perovskite nanorods and nanocubes, such as those having the structure (C₈H₁₇NH₃)₂(CH₃NH₃)₂Pb₃(IₓBr₁₋ₓ)₁₀, 0>x>1, which were synthesized by facile low temperature synthesis. The perovskite NRs show high PL with very good size distribution. Their bang gap can be tuned by halide exchange varying between 1.9 eV-2.26 eV. The wider band gap observed for these NRs might be related to the characteristic of their 2D structure, due to the use of OAI in their synthesis. XRD, ED, and FFT provide evidence for the crystallographic structure of these NRs. Studying different ligand ratios (OAI/OAc) of the NRs revealed their formation mechanism. These 2D perovskite NRs have excellent potential to be used in variety of optoelectronic applications.

### EXPERIMENTAL

Precursor synthesis. Octyl ammonium iodide (OAI) was synthesized by reacting 1 mL of octylamine (99%, Sigma) with 2 mL of hydroiodic acid (57 wt % in water, Aldrich) and 14 mL of distilled water in 100 mL round bottom flask at 0° C. for 2 hr while stirring. The precipitate was recovered by evaporating the solvents at 50° C. using a rotary evaporator. The white raw product was washed with diethyl ether. The washing step was repeated several times. After filtration, the solid was collected and dried at 60° C. in a vacuum oven for 24 hr.

Methyl ammonium iodide/bromide (MAI/MABr) was synthesized by reacting 27.8 mL of methylamine (40% in methanol, TCI) with 30 mL of hydroiodic acid (57 wt % in water, Aldrich) or 23.32 mL of hydrobromic acid (48 wt % in water, Aldrich) in a 250 mL round bottom flask at 0° C. for 2 hrs while stirring. The precipitate was recovered by evaporating the solvents at 50° C. using a rotary evaporator. The white raw product was washed with diethyl ether. The washing step was repeated several times. After filtration, the solid was collected and dried at 60° C. in a vacuum oven for 24 hr.

NRs synthesis. 1M PbI₂/PbBr₂ (99%, Aldrich) and 0.63M MAI/MABr/MAI:MABr=1:1 solutions in DMF (Aldrich) were prepared under nitrogen atmosphere. The solutions were heated on a hot plate at 83° C. until fully dissolved. 15 mg OAI and 100 μL oleic acid (technical grade, 90%, Aldrich) were mixed with 2 mL octadecene (technical grade, 90%, Aldrich) in a small vial for an hour. Then 100 μL of the 0.63M MAI/MABr/MAI:MABr=1:1 solutions in DMF were added, followed by the addition of 50 μL of 1M PbI₂/PbBr₂ solution. Finally, 5 mL of chloroform (biolab) were added. The vial was centrifuged at 3000 rpm for 1 minute. Then the liquid phase was transformed into a clean vial, and again centrifuged for 5 minutes at 6000 rpm. In the case of various ligand compositions, the syntheses include the following ratio OAI/OAc: 100% OAc, 0.075, 0.186, 0.250 and 100% OAI.

Characterization. Transmission electron microscopy (TEM) and electron diffraction (ED) observations were carried out using a Tecnai F20 G2 (FEI Company, USA). The samples were prepared as follows: 3 μL drop of the NRs dispersion was placed on a copper grid coated with amorphous carbon film, followed by evaporation of the solvent by a vacuum pump. FFT was done using the program “digital micrograph”. Absorption spectra were recorded using Jasco V-670 spectrophotometer. Photoluminescence (PL) measurements were performed using L shaped spectrophotometer (Edinburgh Instruments FL920). The samples were excited using at 400 nm. The emission was collected in 90 degrees at the range of 450-800 nm. Photoluminescence quantum yields (PL-QY) were measured using Hamamatsu absolute PL-QY spectrometer C11347. Transmission (for the Tauc plots) spectra was measured using Varian Cary 5000 UV-vis-NIR spectrophotometer. X-ray powder diffraction measurements were performed in grazing incidence X-ray diffraction (GIXRD) mode on the D8 Advance Diffractometer (Bruker AXS, Karlsruhe, Germany) with a goniometer radius of 217.5 mm, a secondary graphite monochromator, 2° Soller slits and a 0.2 mm receiving slit. XRD patterns within the range 5° to 60° 2θ were recorded at room temperature using CuKa radiation (1¼ 1.5418° A) with the following measurement conditions: tube voltage of 40 kV, tube current of 40 mA, step-scan mode with a step size of 0.02° 2θ and counting time of 1-3 s per step. The value of the grazing incidence angle was 2.5°.

Processes for the Preparation of Nanoparticles of the Invention—

The NPs of the invention, may be prepared as follows:
preparing separate precursor's solution(s), e.g., under inert conditions, and causing solubilization of the precursor materials;
mixing the precursor's solutions under conditions permitting formation of the nanoparticles, the conditions being as defined herein; and
optionally separating the thus obtained nanoparticles.

For some applications, the nanoparticles are separated and used, while for other applications, the medium containing the nanoparticles may be used as prepared.

In an exemplary procedure, nanoparticles of the invention were formed as follows:
1) PbI₂ or PbBr₂ in a solvent was prepared.
2) MAI or MABr in a solvent was prepared.
3) The solutions were mixed together and the mixture was permitted to form nanopartciles.
4) The nanoparticles were isolated or maintained in the medium.

Alternatively, the following process was utilized:
1) A solution of PbI₂ or PbBr₂ in dimethylformamide (DMF) was prepared. 2) A solution of MAI or MABr in DMF was prepared.
3) A solution of octylammonium iodide (OAI), oleic acid (OAc) and octadecene was prepared.
4) The three solutions were combined and allowed to form nanoparticles.

Under specific conditions, the following were used:
1) A solution of PbI₂ or PbBr₂ in dimethylformamide (DMF) was prepared. The solution was heated at 80° C.-85° C.
2) A solution of MAI or MABr in DMF was prepared. The solution was heated at 80° C.-85° C.
3) A solution of octylammonium iodide (OAI), oleic acid (OAc) and octadecene were formed at 80° C.
4) The MAI/MABr/mixture of both solutions in DMF was added to the mixture of OAI+OAc+octadecene at 80° C.
5) The mixture was centrifuged to afford the nanoparticles.

In an exemplary method:
1) 1M solution of PbI₂ or PbBr₂ in dimethylformamide (DMF) was prepared under N₂ atmosphere conditions. The solutions were placed on a hot-plate at 80° C.-85° C. until they were clear.
2) 0.63M solution of MAI or MABr in DMF was prepared in N₂ glovebox. For the mixture perovskite preparation, solution of MAI+MABr in DMF as prepared, so that the total molar concentration as 0.63M, for example: 250 μL of 0.315M solution of MAI in DMF was mixed with 250 μL of 0.315M solution of MABr in DMF. The solutions were placed on a hot-plate at 80° C.-85° C. until they were clear.
3) 0.015 g of octylammonium iodide (OAI)+100 μL of oleic acid (OAc)+2 mL of octadecene were mixed at 400 rpm at 80° C. for about 1 hour.
4) 100 μL of the above MAI/MABr/mixture of both solution in DMF was added to the mixture of OAI+OAc+octadecene while mixing at 400 rpm and heating at 80° C. 50 μL of the above 1M PbI₂/PbBr₂ solution in DMF was added afterwards. The mixture was left for 1 minute of mixing at 400 rpm under heating (80° C.), and then 5 mL of chloroform were added (the temperature of the chloroform was room temperature). Color varied from clear bright yellow to the perovskite color (depending on the halides which were used).
5) The mixture was centrifuged at 3000 rpm for 1 minute. Then the liquid was moved to a clean vial, and again centrifuged at 6000 rpm for about 5 minutes. The clear solution contained the nanorods.

TEM of the obtained nanorods:

TABLE 2
Electron diffraction results of (C₈H₁₇NH₃)₂(CH₃NH₃)₂Pb₃I₁₀,
NRs: d-spacings and their corresponding Miller indices.

| d-spacing (±0.04 Å) | hkl |
|---|---|
| 3.108 | (220) |
| 1.743 | (226) |
| 1.888 | (422) |

1.-50. (canceled)

51. A perovskite nanoparticle selected from a nanorod and a nanocube, the nanoparticle having a length of between 3 and 200 nm.

52. A perovskite nanoparticle selected from a nanorod and a nanocube, the nanoparticle having an aspect ratio of between 1 and 100.

53. The nanoparticle according to claim 51, having an aspect ratio of between 1 and 100.

54. The nanoparticle according to claim 51, wherein the nanorod is of a perovskite material comprising at least one organic-inorganic perovskite.

55. The nanoparticle according to claim 51, wherein the perovskite is or comprises a lead halide.

56. A perovskite nanoparticle selected from a nanorod and a nanocube, the nanoparticle having an aspect ratio of between 1 and 100, the nanoparticle being of a perovskite material comprising lead halide.

57. The nanoparticle according to claim 56, wherein the organic-inorganic perovskite is of the formula R₂(A)ₙ₋₁MₙX₃ₙ₊₁ (1<n), wherein R is an organic cation, A is an organic cation, M is a metal and X is a halogen.

58. A process for preparing perovskite nanoparticles, the nanoparticles being selected from perovskite nanorods and nanocubes, the process comprising treating a solution comprising precursors of at least one perovskite material under conditions allowing growth of the perovskite nanoparticles.

59. The process according to claim 58, further comprising obtaining one or more organic cation precursors solution, optionally containing an anion precursor of the perovskite material.

60. The process according to claim 59, further comprising two or more organic cation precursors solutions, wherein one or more organic cation precursor comprises a long carbon chain, while another organic cation comprises a short carbon chain.

61. The process according to claim 60, further comprising obtaining one or more anion precursors solution containing an anion precursor of the perovskite material.

62. The process according to claim 61, further comprising obtaining one or more ligand precursors solution, optionally containing an anion precursor of the perovskite material.

63. The process according to claim 62, further comprising contacting the metal precursors solution with the organic cation precursors solution and optionally with the anion precursors solution of the perovskite material to afford a mixture.

64. The process according to claim 63, wherein the metal precursor solution comprises at least one lead halide.

65. The process according to claim 64, wherein the lead halide is PBI₂ and/or PbBr₂.

66. The process according to claim 63, wherein the metal precursor solution comprises at least one organic solvent.

67. The process according to claim 66, wherein the organic cation precursor solution comprises at least one organic cation precursor selected from octylamine iodide, octylamine bromide, methylamine iodide, methylamine bromide, decylamine iodide, decylamine bromide, octadecylamine iodide and octadecylamine bromide.

68. The process according to claim 58, wherein the conditions allowing growth of the perovskite nanoparticles comprise mixing the solution at room temperature or at a temperature below 200° C., below 100° C., below 90° C. or below 80° C.

69. The process according to claim 58, comprising:
1) obtaining a solution of at least one lead halide;
2) obtaining a solution of at least one amine selected from methylamine iodide or methylamine bromide; and
3) mixing solutions (1) and (2) under conditions permitting formation of the nanoparticles.

70. The process according to claim 69, comprising:
1) obtaining a solution of PbI₂ or PbBr₂ in a solvent;
2) obtaining a solution of methylamine iodide or methylamine bromide in a solvent;
3) obtaining a solution of octylammonium iodide (OAI), oleic acid (OAc) and octadecene;
4) mixing solutions (1), (2) and (3) under conditions permitting formation of the nanoparticles.
